(19) United States
(12) Patent Application Publication
(10) Pub. No.: US 2007/0030013 A1
(43) Pub. Date: Feb. 8, 2007

(54) Noise measurement semiconductor apparatus

(75) Inventor: Hideki Tabata, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/494,699

(22) Filed: Jul. 28, 2006

(30) Foreign Application Priority Data
Aug. 2, 2005 (JP) 2005-223620

(51) Int. Cl. G01R 29/26

(52) U.S. Cl. 324/613

(57) ABSTRACT

A noise measurement semiconductor apparatus for measuring 1/f noise characteristics generated by a device includes a device to be measured of 1/f noise, a control circuit for providing a control signal to a control terminal of the device, in which the device and the control circuit are formed on the same semiconductor substrate.

### BACKGROUND OF THE INVENTION

1. Field of the Invention

The present invention relates to a noise measurement semiconductor apparatus, and particularly to a noise measurement semiconductor apparatus including a device to be measured and a control circuit of the device or an amplifier circuit for amplifying an output.

2. Description of Related Art

In recent years, more and more analog circuits are replaced with digital circuits in an area of electronics. However needs for analog characteristics of devices are far from decreasing but increasing their importance. It is because that there still are analog circuits that cannot be digitalized. Further, if a clock frequency increases, a difference between logical transition time and stable time of a circuit block is reduced due to a delay in a line, thereby resulting to treat a digital circuit as an analog circuit. Therefore, understanding analog characteristics of devices used in a digital circuit is extremely important.

One of the characteristics must be understood among analog characteristics of a device is a noise characteristics. A noise characteristic can be represented as S/N (Signal/Noise) characteristic, which is a ratio of noise level to a signal level outputted by a device. As more noise included in a signal, quality of the signal is deteriorated, possibly malfunction a circuit. There is a noise of a device called 1/f noise that increases inversely proportional to a frequency. For a MOS transistor, 1/f noise is generated by a trap of a gate oxide film catches and releases a carrier at random. The trap of gate oxide film is generated due to contamination or a crystal defect in the gate oxide film. Such noise is generally subtle, thereby requiring an accurate noise measurement. A noise characteristic measurement apparatus of a device is disclosed in Japanese Unexamined Patent Application Publication No. 2003-149286.

FIG. 7 shows a conventional noise measurement apparatus 700 disclosed in Japanese Unexamined Patent Application Publication No. 2003-149286. The noise measurement apparatus 700 is to measure noise characteristics of a MOS transistor 702 formed on a semiconductor substrate 701. The semiconductor substrate 701 includes measuring terminals that are connected to a source, a drain, and a gate of a MOS transistor 702.

The source of the MOS transistor 702 is connected to a ground potential via one of the measuring terminals. A voltage divided by a resistance group 704, where resistances generated and connected by a battery group 703 are connected in series, is supplied to a measuring terminal connected to the gate of the MOS transistor 702. A variable direct-current voltage supply unit 705 is connected to a measuring terminal connected to the drain of the MOS transistor 702 via a load resistance RL. A noise measurement device 706 is connected to a node between the load resistance RL to measure noise of the MOS transistor 702.

Even with the conventional noise measurement apparatus 700, a voltage source and a measurement device must be connected to measuring terminals of the semiconductor substrate 701 by lines. The lines are required to be certain length depending on a condition for the measurement. Accordingly an external noise intruded into measuring component through the lines.

FIG. 8 is a graph showing a measurement of 1/f noise as an example of noise characteristic of a device. The graph shown in FIG. 8 indicates noise intensity to frequencies. 1/f noise is characterized in that it increases inversely proportional to a frequency. As shown in FIG. 8, where the noise characteristic reaches peaks around 100 Hz, an external noise exerts an influence.

As described in the foregoing, it has been discovered that with the conventional noise measurement apparatus, it is difficult to measure only the 1/f noise characteristic of a device due to an influence of an external noise.

### SUMMARY OF THE INVENTION

According to an aspect of the present invention, there is provided a noise measurement semiconductor apparatus for measuring 1/f noise characteristics generated by a device that includes a device to be measured of 1/f noise, a control circuit for providing a control signal to a control terminal of the device, and an amplifier circuit for amplifying an output of the device, in which the device, the control circuit, and the amplifier circuit are formed on the same semiconductor substrate.

According to another aspect of the present invention, there is provided a noise measurement semiconductor apparatus for measuring 1/f noise characteristics generated by a device that includes a device to be measured of 1/f noise, and a control circuit for providing a control signal to a control terminal of the device, in which the device and the control circuit are formed on the same semiconductor substrate.

According to another aspect of the present invention, there is provided a noise measurement semiconductor apparatus for measuring 1/f noise characteristic generated by a device that includes a device to be measured of 1/f noise, and an amplifier circuit for amplifying an output of the device, in which the device and the amplifier circuit are formed on the same semiconductor substrate.

With the noise measurement semiconductor apparatus according to the present invention, it is possible to significantly shorten the distance between the device and the control circuit by the control circuit for the device being formed on the same substrate as the device. This prevents external noise intruding into a control terminal of the device. Furthermore, by forming the device on the same semiconductor substrate as the amplifier circuit for amplifying an output from the device, it is possible to significantly shorten the distance between the device and the amplifier circuit. This prevents external noise intruding into input terminal of the amplifier circuit, thereby enabling to selectively amplify noise generated by the device to be outputted. As described in the foregoing, the present invention enables to accurately measure the 1/f noise characteristic of the device.

### BRIEF DESCRIPTION OF THE DRAWINGS

The above and other objects, advantages and features of the present invention will be more apparent from the following description taken in conjunction with the accompanying drawings, in which:

FIG. 1 is a view showing a noise measurement circuit according to a first embodiment of the present invention;

FIG. 2 is a view showing a constant voltage supply circuit according to the first embodiment of the present invention;

FIG. 3 is a view showing noise measurement circuit according to a second embodiment of the present invention;

FIG. 4 is a view showing an amplifier circuit according to the second embodiment of the present invention;

FIG. 5 is a view showing a circuit for measuring noise characteristics only for an amplifier circuit according to the second embodiment of the present invention;

FIG. 6 is a view showing a noise measurement circuit according to a third embodiment;

FIG. 7 is a view showing a noise measurement circuit according to a conventional technique; and

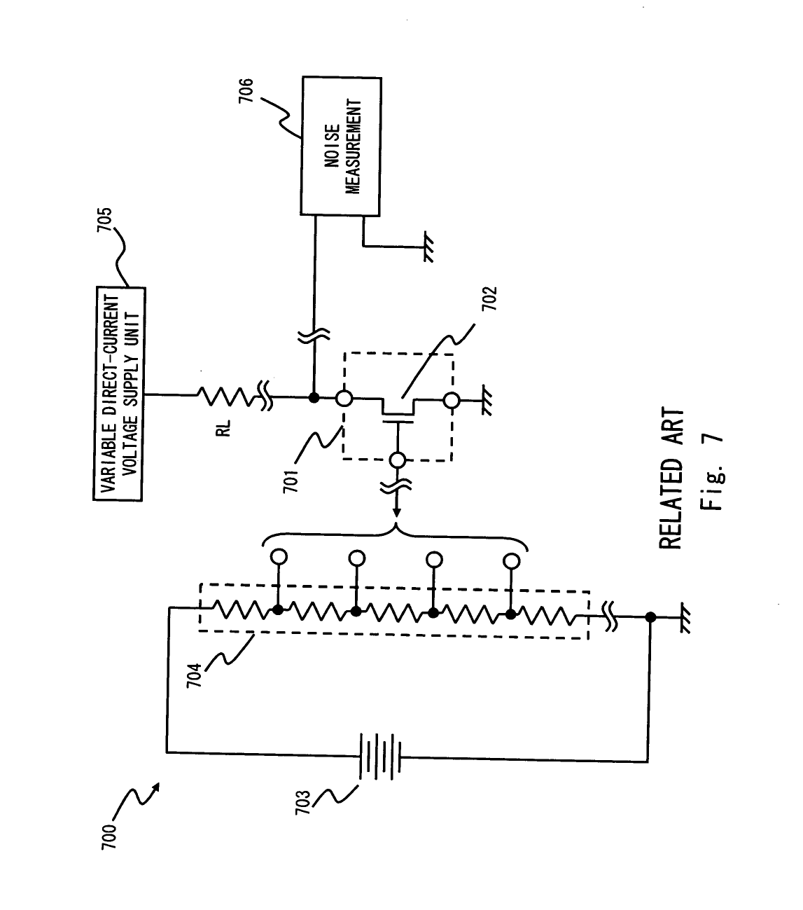

FIG. 8 is a graph showing a relationship between 1/f noise and external noise for a noise measurement circuit according to a conventional technique.

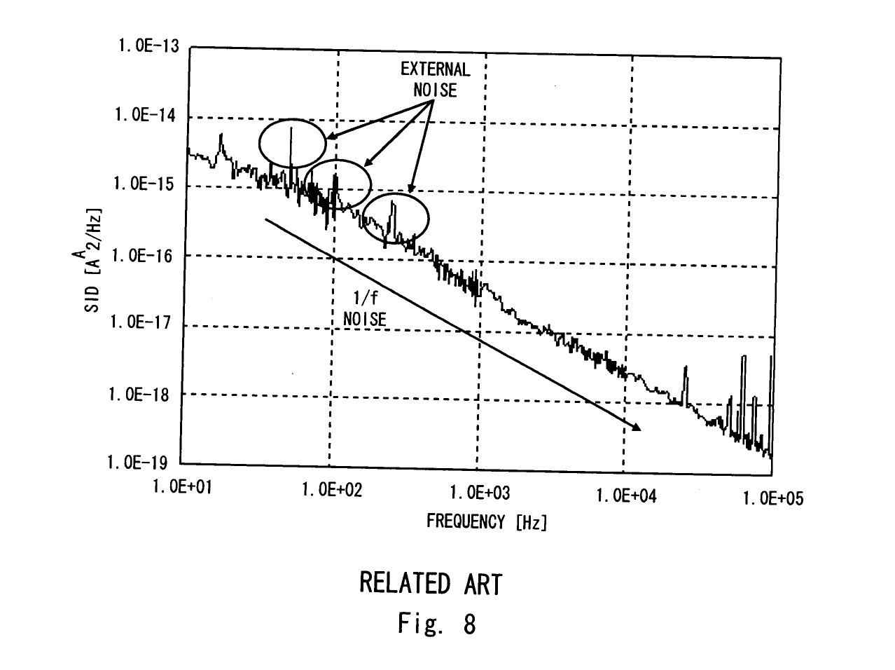

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

First Embodiment

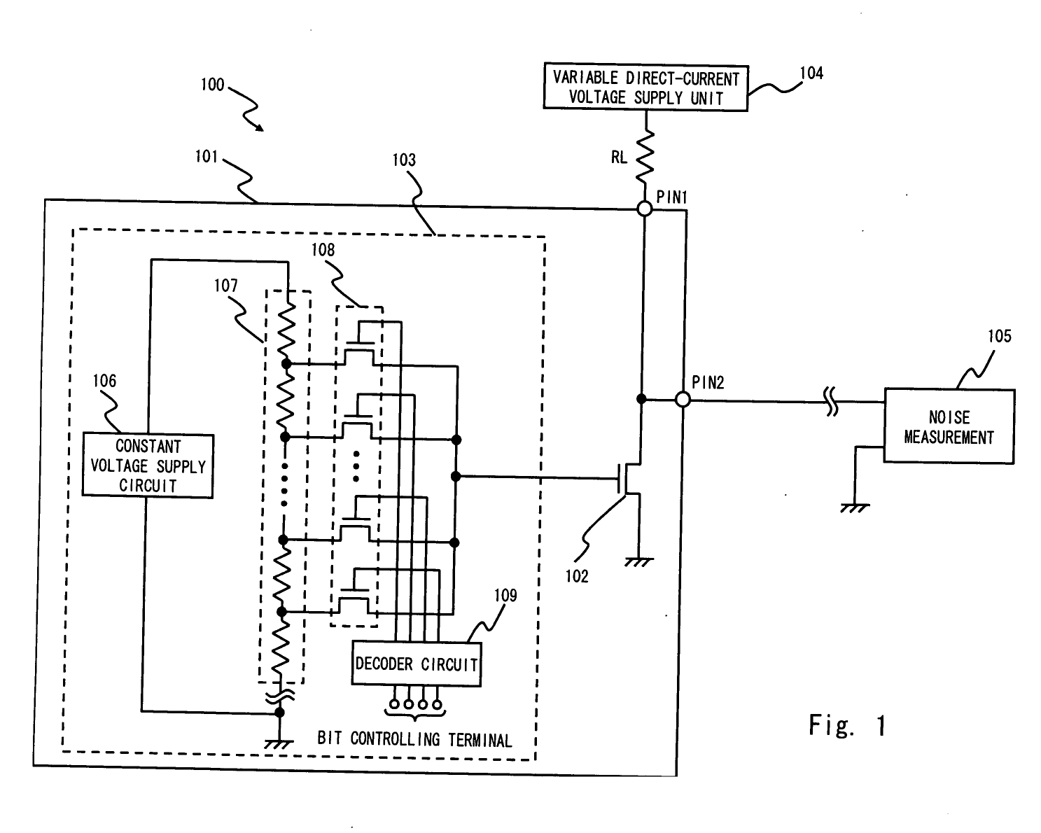

A noise measurement apparatus 100 of a first embodiment is shown in FIG. 1. As shown in FIG. 1, the noise measurement apparatus 100 includes a noise measurement semiconductor apparatus (for example a semiconductor substrate) 101, where a MOS transistor 102, which is to be measured, and a control circuit 103 are formed thereon. Terminal pins 1 and 2 to be connected to a drain of the MOS transistor 102 are formed on the semiconductor substrate 101. A variable direct-current supply unit 104 is connected to the terminal pin 1 via a load resistance RL. A noise measurement device 105 is connected to the terminal pin 2.

A source of the MOS transistor 102 is connected to a ground, and the drain is connected to the terminal pins 1 and 2. The terminal pins 1 and 2 are arranged in a way so that the distance to the MOS transistor 102 is as short as possible. A control signal (for example control voltage) is supplied to a control terminal (for example gate) is supplied from the control circuit 103. The control circuit 103 includes a constant voltage supply circuit 106, a resistance group 107, a switch group 108, and a decoder circuit 109.

The constant voltage supply circuit 106 is a circuit to output a constant voltage. A resistance group 107 having a plurality of resistors connected in series and outputting a plurality of specified voltages, the constant voltage divided according to a resistance division ratio of nodes for the plurality of resistors.

The switch group 108 includes a plurality of MOS transistors. Each sources of the plurality of MOS transistors are connected to nodes between each resistor of the resistance group 107. Gates of the plurality of MOS transistors are connected to a decoder circuit 109. Drains of the plurality of MOS transistors are connected by a node. The node is an output of the control circuit 103 and is connected to the gate of the MOS transistor 102.

The decoder circuit 109 includes terminals for controlling bits. The MOS transistors of the switch group 108 are controlled by signals outputted from the terminals for controlling bits. The decoder circuit 109 makes any one of the MOS transistors of the switch group conductive so as to select any one of voltages outputted from the resistance group 107 to supply the selected voltage to the gate of the MOS transistor 102.

The variable direct-current voltage supply unit 104 is a direct-current voltage source capable of changing voltage value to output. It also supplies a current to the MOS transistor 102, which is to be measured of voltage. One end of the load resistance RL is connected to the variable direct-current voltage supply unit 104, and another end is connected to the drain of the MOS transistor 102 via the terminal pin 1. By the current flowing to the MOS transistor 102, voltage corresponding to an amount of the current is generated in the MOS transistor 102 a terminal of the load resistance RL. That means that the load resistance RL converts the current output of the MOS transistor 102 into voltage. The noise measurement device 105 is to measure a voltage level of the noise. It is for example a noise analyzer or a spectrum analyzer.

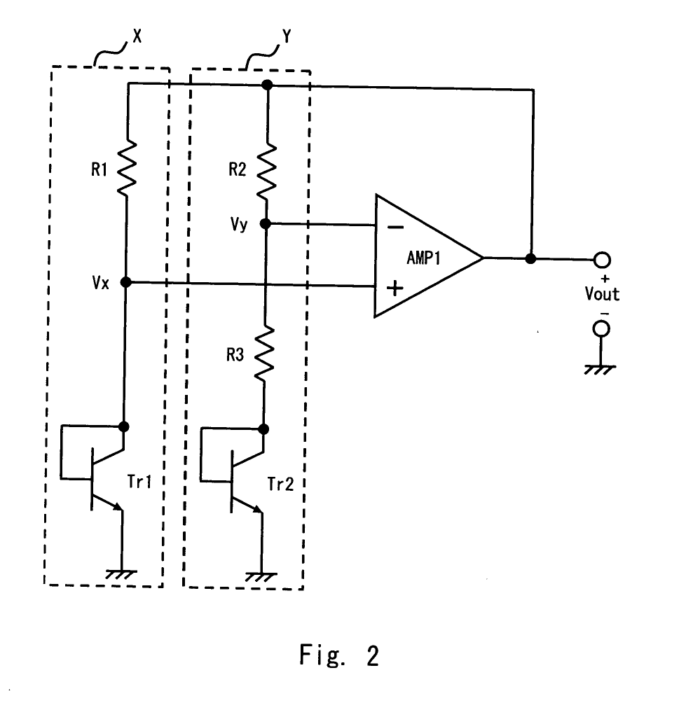

The constant voltage supply circuit 106 in the control circuit 103 is described hereinafter in detail. An example of the constant voltage supply circuit 106 is shown in FIG. 2. The circuit shown in FIG. 2 is a band gap reference circuit, where an output terminal of an amplifier AMP 1 is an output terminal of the constant voltage supply circuit 106. The constant voltage supply circuit 106 includes input portions X and Y which generate input voltage of the amplifier AMP 1.

The input portion X includes a NPN transistor Tr 1 and a resistance R1. An emitter of the NPN transistor Tr 1 is connected to a ground, and a base and a collector is connected, forming a diode connection. Further, the collector of the NPN transistor Tr 1 is connected to an output of the amplifier AMP 1 via a resistor R1. A voltage Vx is generated in a node between the collector of the NPN transistor Tr 1 and the resistor R1. The voltage Vx is inputted to a non-inverted terminal.

The input portion Y includes a NPN transistor Tr 2, resistors R2 and R3. An emitter of the NPN transistor Tr 2 is connected to a ground, and a base and a collector is connected, forming a diode connection. Further, the collector of the NPN transistor Tr 2 is connected to the resistor R3. The resistor R3 is connected to an output of the amplifier AMP 1 via a resistor R2. A voltage Vy is generated in a node between the resistor R2 and R3. The voltage Vy is inputted to an inverted terminal.

A band gap reference circuit generates an output voltage V out, where a voltage Vx equals a voltage Vy, with different input portions X and Y configuration. In this example, the NPN transistors Tr 1 and Tr 2 are transistors with different emitter size. Furthermore, resistance value of the resistor R1 and R2 are configured to be the same.

An operation of the noise measurement apparatus 100 of the first embodiment is described hereinafter in detail. The noise measurement apparatus 100 of the first embodiment generates a gate voltage of the MOS transistor 102, which is a device to be measured, by the control circuit 103 formed on the same substrate as the MOS transistor 102. A plurality of voltages are generated in the control circuit 103, in which the switch group 108 and the decoder circuit 109 select any one of the voltage therefrom to supply to the MOS transistor 102. A measurer is to select the voltage to be supplied to the MOS transistor 102 according to measurement condition of the MOS transistor 102.

If a specified voltage is supplied to the gate of the MOS transistor 102 from the control circuit 103, the MOS transistor 102 becomes conductive corresponding to the specified voltage and passes a current. A voltage based on the amount of current flowing the MOS transistor 102 is generated in the load resistance RL of the MOS transistor 102 side. The current flowing the MOS transistor 102 is supplied from the variable direct-current supply unit 104, which is separated from the semiconductor substrate 101.

In this example, an amount of current flowing the MOS transistor 102 fluctuates if a trap of a gate oxide film, which is generated due to contamination of the gate oxide film or a crystal defect, catches and releases a carrier at random. The fluctuation in the amount of current is represented as a noise level, as a fluctuation of voltage in the load resistance RL. The noise measurement device 105 measures the noise level.

With the noise measurement apparatus 100 of the first embodiment, a gate voltage of the MOS transistor 102, which is a device to be measured, is supplied by the control circuit 103 formed on the same semiconductor substrate as the MOS transistor 102. This makes it possible to shorten the distance between the MOS transistor 102 and the control circuit 103, as compared to a case the MOS transistor 102 and the control circuit 103 are separated. Accordingly it virtually eliminates the possibility that an external noise intruded into a line connecting the MOS transistor 102 and the control circuit 103. To be more specific, an external noise intruded into the line connecting the MOS transistor 102 and the control circuit 103 will not be amplified by the MOS transistor 102. Therefore, with the noise measurement apparatus 100 of the first embodiment, it is possible to accurately measure noise characteristic of a device, even if the noise is subtle.

The external noise intruded into the line is often a low frequency noise, for example a power supply noise (such as hum). This embodiment is effective in measuring low frequency noise (for example 1/f noise) characteristics of a device itself.

To measure 1/f noise of the transistor 102, which is a circuit to be measured, it is necessary to eliminate an influence of noise generated by transistors forming a measurement circuit such as the constant voltage supply circuit 106 and the switch group 108. This can be achieved using a known method, by reducing the noise. For example if the transistors are MOS transistors, and a ratio between a gate length L and a gate width W is constant, it is well known that 1/f noise can be reduced more with a longer gate length L. Accordingly by having longer gate length L of transistors forming the constant voltage supply circuit 106 and the switch group 108 as against to the transistor 102, noise can be reduced.

As shown in FIG. 2, if Tr 1 and Tr2, which are to be band gap references of the constant voltage supply circuit 106, are bipolar transistors, reducing an area where a base region contacting an emitter area reduces total amount of current flowing the base region, thereby reducing noise. As described in the foregoing, it is possible to reduce noise generated by the constant voltage supply circuit 106 and the switch group 108 that constitute a measuring component of the MOS transistor 102 to a level low enough to have no influence on the measurement. It means that the noise generated by the measuring component does not influence the noise generated by the MOS transistor 102, which is a device to be measured. Therefore the noise measurement apparatus 100 of this embodiment enables to accurately measure the noise generated by a device.

Second Embodiment

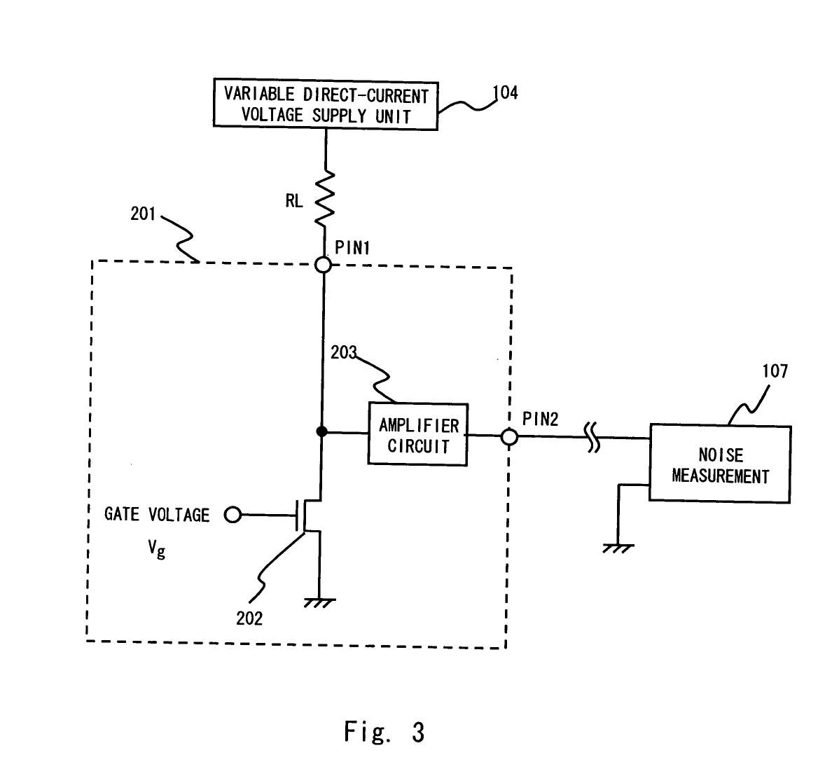

A noise measurement apparatus of a second embodiment is shown in FIG. 3. In FIG. 3, components identical to those in the first embodiment are denoted by reference numerals identical to those therein with detailed description omitted. As shown in FIG. 3, the noise measurement apparatus 200 includes a MOS transistor 202, which is a device to be measured, and an amplifier circuit 203 for amplifying noise of the MOS transistor 202 formed on the same semiconductor substrate as the MOS transistor 202. A noise measurement device 105 measures the noise amplified by the amplifier circuit 203 via a terminal pin 2 on the semiconductor substrate 201.

In this embodiment, a gate voltage of the MOS transistor 202 is supplied by a control circuit formed on the same semiconductor substrate 201 as with the first embodiment, or by a voltage source separated from the semiconductor substrate. Further, a drain of the MOS transistor 202 is connected to an end of a load resistance RL via a terminal pin 1. Another end of the load resistance RL is connected to a variable direct-current voltage supply unit 104. A source of the MOS transistor 202 is connected to a ground.

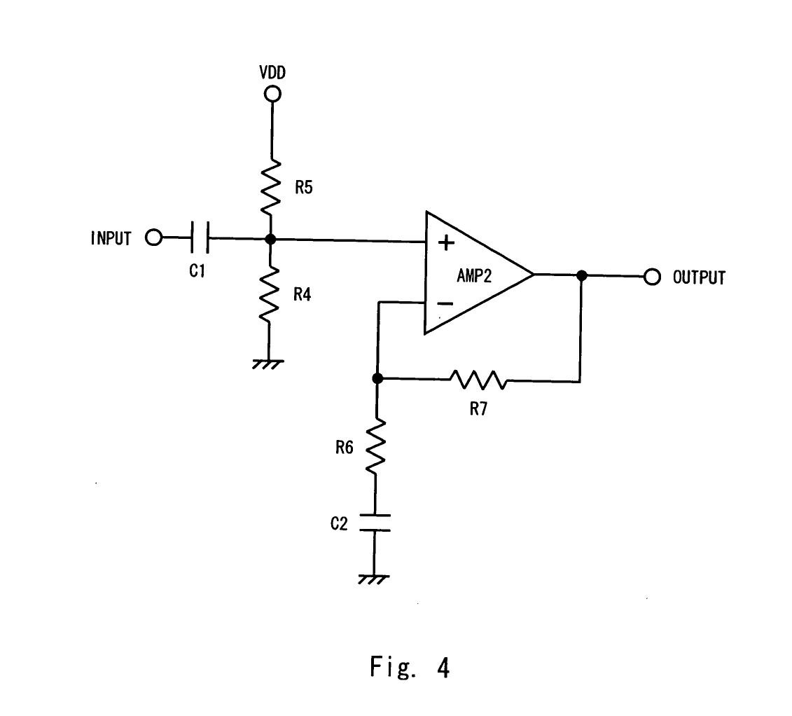

An input terminal of the amplifier circuit 203 is connected to a line that is connected to the drain of the MOS transistor 202 and is near the MOS transistor 202. A noise measurement device is connected to the line via the amplifier circuit 203. An example of the amplifier circuit 203 is shown in FIG. 4. As shown in FIG. 4, the amplifier circuit 203 is a circuit for amplifying only a noise signal, which is an alternating-current signal, and outputting the noise signal, by a coupling condenser C1 inputting only alternating-current component to an amplifier AMP 2. The amplifier circuit 203 and the MOS transistor 202 are desirably supplied with different ground potentials so as to isolate an influence of noise.

An operation of the noise measurement apparatus 200 of the second embodiment is described hereinafter in detail. The noise measurement apparatus 200 of the second embodiment supplies a voltage to the gate of the MOS transistor 202, which is a device to be measured. Making the MOS transistor 202 conductive causes a voltage and noise to be generated in the MOS transistor 202.

The generated noise is amplified by the amplifier circuit 203, and the amplified noise is measured by the noise measurement device 105. The measurement result obtained by the noise measurement device 105 must be corrected in consideration of a voltage amplification factor of the amplifier circuit 203.

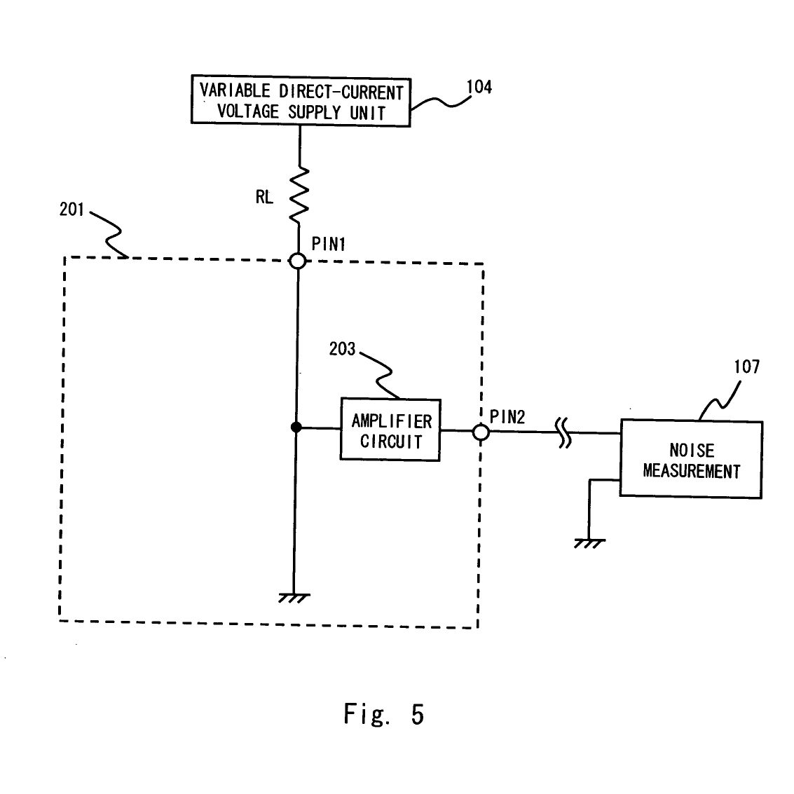

In the second embodiment, the noise generated in the MOS transistor 202 is outputted via the amplifier circuit 203. Accordingly an influence of the noise needs to be measured in advance. A noise measurement circuit of the amplifier circuit 203 is shown in FIG. 5.

As shown in FIG. 5, an input of the amplifier 203 is connected to a ground in place of the MOS transistor 202 connected to an input of the amplifier circuit 203 when measuring noise of the MOS transistor 202. This enables to measure noise characteristic of only the amplifier circuit 203, the load resistance RL, and a variable direct-current voltage supply unit 104.

With the noise measurement circuit shown in FIG. 5, noise characteristic of only the amplifier circuit 203, the load resistance RL, and the variable direct-current voltage supply unit 104 is measured. Further, by utilizing the measurement result, more accurate noise characteristic of the MOS transistor 202 can be obtained.

With the noise measurement apparatus 200 of the second embodiment, the noise generated in the MOS transistor 202, which is a device to be measured, is amplified and outputted by the amplifier circuit 203. By doing this, even if an external noise intruding into a line connecting the semiconductor substrate 201 and the noise measurement device 105, it enables to increase a level of the noise generated in the MOS transistor 202 as against to the external noise. Specifically, an influence of the external noise to the noise generated in the MOS transistor 202 can be reduced.

It further enables to measure noise characteristic of only the amplifier circuit 203, a load resistance RL, and a variable direct-current voltage supply unit 104. Therefore, it is possible to measure noise characteristic with higher accuracy by considering the noise measurement result of the MOS transistor 202.

Furthermore as with the first embodiment, by forming a control circuit for supplying a gate voltage of the MOS transistor 202, which is a device to be measured, and the MOS transistor 202 on the same semiconductor substrate, noise characteristic can be measured with higher accuracy.

It is possible to reduce 1/f noise generated in a known method as with the first embodiment in the constant voltage supply circuit 106, the switch group 108, and the amplifier circuit 203, which are formed on the same substrate and form a measuring component for the MOS transistor 102, to a level low enough to have no influence on the measurement. It means that the noise generated by the measuring component does not influence the noise generated by the MOS transistor 102, which is a device to be measured. Accordingly with the noise measurement apparatus 200 of this embodiment, noise generated by a device itself can be measured accurately.

Third Embodiment

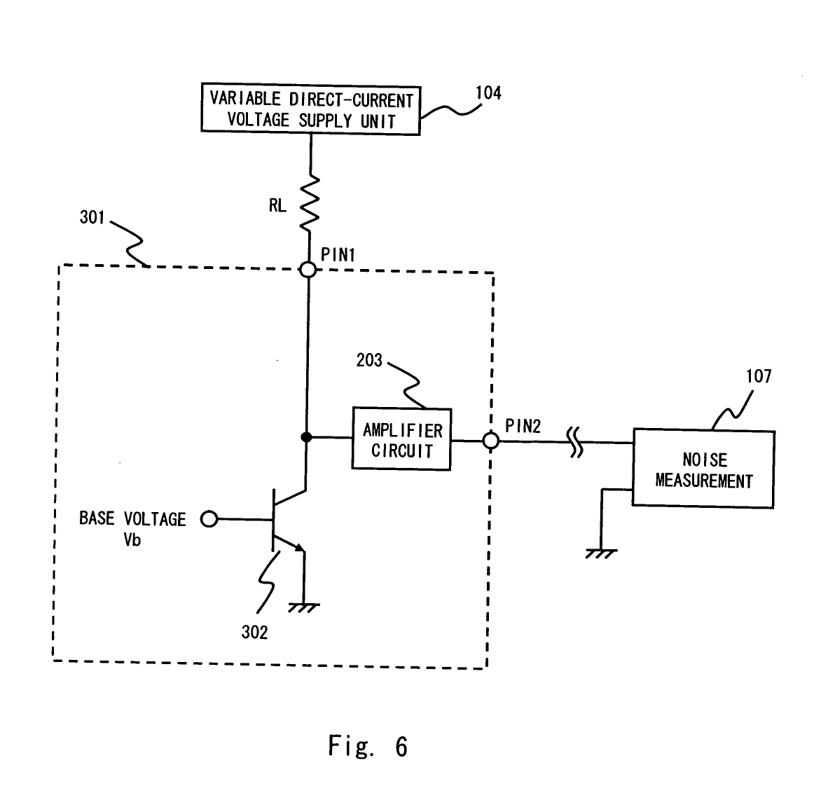

A noise measurement apparatus of a third embodiment is shown in FIG. 6. In contrast to the noise measurement apparatus 200 of the second embodiment measuring noise characteristics of the MOS transistor 202 formed on the semiconductor substrate 201, the noise measurement apparatus of the third embodiment measures noise characteristics of a bipolar transistor formed on a semiconductor substrate 300. In FIG. 6, components identical to those the first and the second embodiments are denoted by reference numerals identical to those therein with detailed description omitted.

In the noise measurement apparatus 300 of the third embodiment, a transistor 302 is formed on the semiconductor substrate 301. It is equivalent to the second embodiment except for the NPN transistor instead of the MOS transistor 202. An emitter, a collector, and a base of the NPN transistor 302 correspond respectively to a source, drain, and a gate of the MOS transistor 202.

A voltage is supplied to the base of the NPN transistor 302 by a control circuit formed on the semiconductor substrate 301 as with the first embodiment or by a voltage source separated from the semiconductor substrate. In this embodiment, a control circuit may be connected to the base of the NPN transistor 302 for controlling the NPN transistor 302 by a current because the NPN transistor is to be measured.

To be more specific, with the noise measurement apparatus 300 of the third embodiment, noise characteristics can be measured as accurate as the first and the second embodiment even with a bipolar transistor.

Though a preferred embodiment of the present invention is described in detail in the foregoing, the present invention is not restricted to the above-mentioned embodiment but various changes may be made. For example the control circuit is not restricted to the above embodiment but can be a voltage source suppressed to generate noise appropriately. The amplifier circuit can be an amplifier circuit suppressed to generate noise appropriately. Further, Tr 1 and Tr 2 of the band gap reference circuit can be realized by MOS transistors suppressed to generate noise with longer gate length L.

It is apparent that the present invention is not limited to the above embodiment and it may be modified and changed without departing from the scope and spirit of the invention.

What is claimed is:

1. A noise measurement semiconductor apparatus for measuring 1/f noise characteristics generated by a device comprising:
a device to be measured of 1/f noise;
a control circuit for providing a control signal to a control terminal of the device; and
an amplifier circuit for amplifying an output of the device,
wherein the device, the control circuit, and the amplifier circuit are formed on the same semiconductor substrate.

2. The noise measurement semiconductor apparatus according to claim 1, wherein the control circuit comprises:
a constant voltage supply circuit for outputting a constant voltage;
a resistance group having a plurality of resistors connected in series and outputting a plurality of specified voltages, the constant voltage divided according to a resistance division ratio of nodes for the plurality of resistors;
a switch group having a plurality of switch devices connected between the nodes for the plurality of resistors and a control signal of the device; and
a decoder circuit for controlling each of the plurality of switch devices.

3. The noise measurement semiconductor apparatus according to claim 2, wherein the control circuit is comprised of a semiconductor device having less noise than the device.

4. The noise measurement semiconductor apparatus according to claim 1, wherein the control circuit is comprised of a semiconductor device having less noise than the device.

5. A noise measurement semiconductor apparatus for measuring 1/f noise characteristics generated by a device comprising:
a device to be measured of 1/f noise; and
a control circuit for providing a control signal to a control terminal of the device,
wherein the device and the control circuit are formed on the same semiconductor substrate.

6. The noise measurement semiconductor apparatus according to claim 5, wherein the control circuit comprises:
a constant voltage supply circuit for outputting a constant voltage;
a resistance group having a plurality of resistors connected in series and outputting a plurality of specified voltages, the voltage divided according to a resistance division ratio of nodes for the plurality of resistors;
a switch group having a plurality of switch devices connected between the nodes for the plurality of resistors and a control signal of the device; and
a decoder circuit for controlling each of the plurality of switch devices.

7. The noise measurement semiconductor apparatus according to claim 5, wherein the control circuit is comprised of a semiconductor device having less noise than the device.

8. A noise measurement semiconductor apparatus for measuring 1/f noise characteristics generated by a device comprising:
a device to be measured of 1/f noise; and
an amplifier circuit for amplifying an output of the device,
wherein the device and the amplifier circuit are formed on the same semiconductor substrate.

9. The noise measurement semiconductor apparatus according to claim 8, wherein the control circuit is comprised of a semiconductor device having less noise than the device.

10. A method of measuring 1/f noise characteristics generated by a semiconductor device comprising:
controlling a control terminal of a device to be measured by a control signal outputted from a control circuit formed on the same semiconductor substrate as the device; and
measuring 1/f noise characteristics by a measurement device separated from the semiconductor substrate with an output result of the device that is based on the control.

11. The method of measuring 1/f noise characteristics generated by a semiconductor device according to claim 10, wherein the control circuit is comprised of a semiconductor device having less noise than the device.
